(19) United States
(12) Patent Application Publication
(10) Pub. No.: US 2019/0372117 A1
(43) Pub. Date: Dec. 5, 2019

(54) HIERARCHICAL NANOSTRUCTURED SILICON-BASED ANODES FOR USE IN A LITHIUM-ION BATTERY

(71) Applicant: THE BOARD OF REGENTS FOR OKLAHOMA STATE UNIVERSITY, STILLWATER, OK (US)

(72) Inventors: Malay Jana, Tulsa, OK (US); Raj N. Singh, Tulsa, OK (US)

(21) Appl. No.: 16/487,395

(22) PCT Filed: Feb. 22, 2018
(86) PCT No.: PCT/US2018/019244

§ 371 Date: Aug. 20, 2019

Related U.S. Application Data
(60) Provisional application No. 62/462,417, filed on Feb. 23, 2017.

(51) Int. Cl. H01M 4/38; H01M 4/134; C09K 13/04; H01L 21/306

(52) U.S. Cl. CPC H01M 4/386; H01L 21/30604; C09K 13/04; H01M 4/134

(57) ABSTRACT

The conventional Li-ion batteries use graphite anode, which has a theoretical specific capacity of 372 mAh/g, which limits their application for high capacity energy storage devices. Silicon has been tried because of its high theoretical specific capacity (4200 mAh/g) but the stress created due to volume expansion during intercalation of Li causes fracture and hence electrical isolation between particles and current collector leading to capacity loss. The present invention demonstrates the design of metallurgical grade polycrystalline silicon anode to achieve high reversible capacity (−1000 mAh/g) with high coulombic efficiency (99.6%), and low cost.

### CROSS REFERENCE TO RELATED APPLICATION

This application claims the benefit of U.S. Provisional Patent Application Ser. No. 62/462,417 filed on Feb. 23, 2017, and incorporates said provisional application by reference into this document as if fully set out at this point.

### TECHNICAL FIELD

This disclosure relates generally to batteries and, more specifically, to lithium-ion batteries.

### BACKGROUND

The use of green energy sources is one of the major challenge and driving force in current energy market. This will not only solve the dependence on limited fossil fuel but also the issue of global warming due to the greenhouse gas emission. However, the effective use of any renewable energy sources demands energy storage. Li-ion batteries are the major storage system, which is currently used in a variety of applications from regular electronic devices to electric cars. At present the Li-ion batteries mostly use graphite as anode with maximum specific capacity of 372 mAh/g, which limits their application in high capacity batteries. The low capacity not only makes it difficult for miniaturization of the device but also makes it difficult to use it in grid storage or in electric vehicles. Thus, there is a growing interest to use other electrode materials to store more electrical energy for higher capacity.

Silicon is a promising choice as anode material for Li-ion batteries because of its high theoretical specific capacity of ˜4200 mAh/g, which is more than ten times that of commercial graphite. But Si undergoes enormous (300-400%) volume expansion via an alloying process during intercalation. This large volume change primarily causes significant mechanical stress, leading to fracture and electrical isolation of the active materials, which basically results in huge loss of capacity and hinders its use in batteries. There are also secondary issues of fracture of Si particles, which leads to uncontrolled growth of the solid electrode-electrolyte interphase on newly exposed surfaces thereby impacting the cell resistance. In short, all these problems result in capacity fading and poor cycling performance. Therefore, it is vital to synthesize and process the silicon electrode in a way that provides high reversible capacity by managing the stress associated with the volume expansion.

Researchers have tried to solve this problem associated with silicon using various ways. Besides the theoretical understanding of volume change and stress calculation, most of the research was confined to reducing the dimension of the particle size, so that the increased surface area can minimize or accommodate the stress developed in the material and associated volume expansion. Thus, over the last several year's various kinds of nanostructures of silicon such as nanowires, nanoparticles, hollow spheres, core shell structures have been employed but they are not easy to scale or cost effective as they mostly employ single crystalline nanostructured silicon and require high precision fabrication technology, which are neither the common practice for Li-ion battery industry nor desirable. Majority of these studies were focused on highly advanced architectures created by means of 3D patterning and electrochemical etching of wafer, which are not desirable approaches for today's manufacturing practices used for high capacity Li-ion batteries, especially for electric vehicles. Also, there are reports that the intercalation of silicon by lithiation depends on crystalline orientation. So, defining the orientation and aligning the particular favored orientation to the lithiation direction is also a challenging task for single crystalline based silicon electrode materials.

Other researchers have sought to make composite electrodes with different allotropes of carbon including graphene and carbon nanotube (CNT). Also, there are few reports available on the use of porous current collector or addition of some additives of metal nanoparticles or film or uses of some other electrolytes or binders, to improve the performance. All these studies add more cost to the final product due to either extra processing steps or addition of extra amount/number of advanced nanomaterials, but the capacity fading problem remains. Currently, one of the biggest challenges is getting high reversible capacity from Si-based electrodes, which can be robust, easy to scale, cost effective, and compete with the graphite-based electrode materials in terms of performance, manufacturing practice, cost and robustness.

Thus, what is needed is a hierarchical nanostructured silicon-based anode for Lithium-ion Battery. It should be based on a robust, innovative process for realizing a high capacity anode based on easily available metallurgical low-grade polycrystalline silicon powder.

Before proceeding to a description of the present invention, however, it should be noted and remembered that the description of the invention which follows, together with the accompanying drawings, should not be construed as limiting the invention to the examples (or embodiments) shown and described. This is so because those skilled in the art to which the invention pertains will be able to devise other forms of this invention within the ambit of the appended claims.

### SUMMARY OF THE INVENTION

According to one embodiment, there is provided herein a hierarchical nanostructured silicon-based anode for lithium-ion battery. An embodiment is given herein that is based on a robust, innovative process for realizing a high capacity anode based on easily available metallurgical low-grade polycrystalline silicon powder. It employed a three-step technique for creating (i) nanostructured pores and nanofibers on silicon, (ii) uniform and homogeneous mixing with superconducting carbon and sudden conversion to a gel of a solution containing the etched silicon and superconducting carbon suspended in furfuryl alcohol to maintain dispersion and (iii) then coating with furfuryl alcohol derived carbon. The battery performance of the processed anodes was then evaluated in half cell (vs. Li) configuration displaying improved capacity retention.

Conventional Li-ion batteries use graphite anode, which has a theoretical specific capacity of 372 mAh/g, which limits their application for high capacity energy storage devices. Silicon has been tried because of its high theoretical specific capacity (4200 mAh/g) but the stress created due to volume expansion during intercalation of Li causes fracture and hence electrical isolation between particles and current collector leading to capacity loss. Various embodiments of the present invention demonstrate the design of metallurgical grade polycrystalline silicon anode to achieve high reversible capacity (e.g., about 1000 mAh/g) with high coulombic efficiency (e.g. about 99.6%), and low cost.

The foregoing has outlined in broad terms some of the more important features of the invention disclosed herein so that the detailed description that follows may be more clearly understood, and so that the contribution of the instant inventors to the art may be better appreciated. The instant invention is not to be limited in its application to the details of the construction and to the arrangements of the components set forth in the following description or illustrated in the drawings. Rather, the invention is capable of other embodiments and of being practiced and carried out in various other ways not specifically enumerated herein. Finally, it should be understood that the phraseology and terminology employed herein are for the purpose of description and should not be regarded as limiting, unless the specification specifically so limits the invention.

### BRIEF DESCRIPTION OF THE DRAWINGS

These and further aspects of the invention are described in detail in the following examples and accompanying drawings.

FIG. 1 contains an exemplary morphology of etched polycrystalline silicon particles with silicon nanofibers on their surfaces.

FIGS. 2A-2C contains exemplary plots, respectively, of (A) FTIR spectra of the FFA coated sample with or without HCI. (B) Raman spectra of the carbon coated sample, which was coated with FFA and HCI. (C) Raman spectra taken on the similar particles after carbonization, which were coated with FFA and FFA+HCI.

FIG. 3 contains an embodiment of an X-ray diffraction pattern of the furfuryl alcohol derived carbon coated etched silicon networked with superconducting carbon and the raw polycrystalline silicon powder as a reference.

FIGS. 4A and 4B contain SEM images of the (A) pristine polycrystalline silicon particles, (B) FFA+HCI derived carbon coated etched silicon particles separated and filled with superconducting carbon.

FIGS. 5A to 5C contain exemplary cyclic voltammetry curves of the (A) pristine polycrystalline silicon, (B) etched porous silicon and (C) coated and etched silicon filled with SCB.

FIG. 6 contains Nyquist plots of as-received polycrystalline Si, etched Si, after etching and coating (before cycling) and the same after 200 cycles for an embodiment.

FIGS. 7A to 7B contain examples, respectively, of: (A) charge-discharge curves for the etched and coated sample up to 200 cycles and (B) specific capacity vs. cycle number of the same sample along with the as-received polycrystalline silicon and etched silicon.

FIG. 8 contains a generalized flowchart that would be suitable for use with an embodiment.

### DETAILED DESCRIPTION

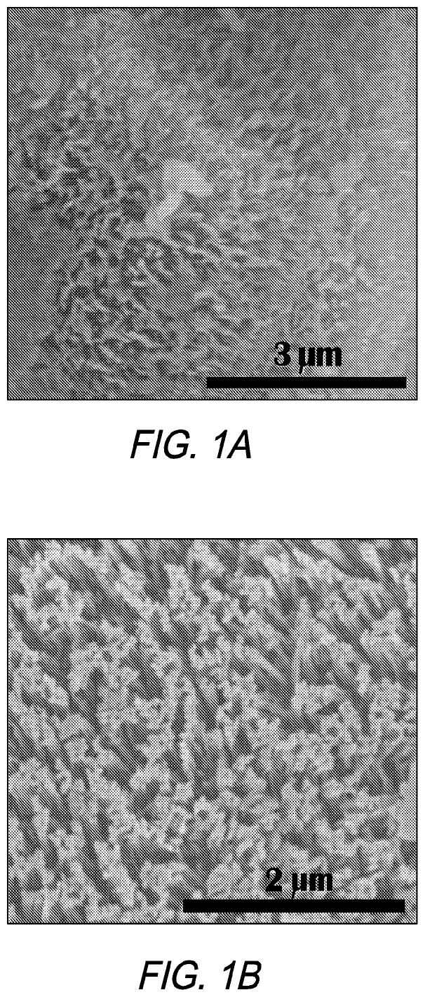

The method for preparing nanostructured silicon-based anodes for use in lithium-ion batteries begins with the step of preparing the desired silicon structure. The desired silicon structure is in powder form with particles having a size range of about 1 μm to about 300 μm. Preferably, each silicon particle carries silicon nanofibers having a length of about 500 nm to about 20 μm and a diameter of about 30 nm to 100 nm. The nanofibers carried by the silicon particles have a separation gap from one another of about 50 nm to about FIGS. 1A and 1B depict the surface of the silicon particles carrying the silicon nanofibers. The length, diameter and gap defining the silicon nanofibers all contribute to the improved characteristics of an anode encompassing these particles.

The method of preparing the desired silicon particles carrying the silicon nanofibers begins with the step of providing dry micron size polycrystalline silicon powder substantially free of carbon residue. The preferred size range of the polycrystalline silicon powder is from about 1 μm to about 300 μm. To generate the desired silicon nanofibers, an etchant solution of silver nitrate in hydrofluoric acid is prepared such that the concentration of silver nitrate is from about 2 to about 6 weight percent in a hydrofluoric acid solution having a molarity of about 4 to about 6. The polycrystalline Silicon powder is added to the silver nitrate/HF solution to produce a dispersion having from about 94% to about 98% by weight polycrystalline silicon powder. A uniform dispersion is maintained by agitation with any convenient means, e.g. rotating, stirring, vibrating and sonicating.

Upon establishment of the desired dispersion, hydrogen peroxide having a molarity of about 0.1 to about 0.8 is added to the dispersion. Addition of hydrogen peroxide continues until resulting mixture contains from about 1 to about 3 vol % of hydrogen peroxide, i.e. an amount of hydrogen peroxide at this concentration sufficient to etch the polycrystalline silicon powder. During the addition of the hydrogen peroxide, the dispersion is maintained by continued agitation of the mixture.

The amount of time necessary to achieve the desired etching, i.e. generation of the silicon nanofibers, is determined by the mass of polycrystalline silicon powder and the concentration of the hydrogen peroxide. For example, if the dispersion contains 2.5 g of polycrystalline silicon powder and the hydrogen peroxide solution consists of 0.6 ml of H₂O₂ in 25 ml of water, the etching process will require from about two to about five hours.

Upon passage of sufficient time to provide the desired etched polycrystalline silicon powder, i.e. a polycrystalline silicon powder carrying silicon nanofibers, the dispersion is neutralized. The preferred neutralizing agent is deionized water. The amount of water required to neutralize the mixture is calculated based on the volume and concentration of the hydrogen peroxide present. Following neutralization, the etched polycrystalline silicon powder is isolated by filtration or other convenient means. The resulting etched polycrystalline silicon powder may contain trace amounts of silver. Therefore, the etched polycrystalline silicon powder is washed with a suitable mineral acid. The preferred mineral acid is nitric acid at a molarity of about 3 to about 10. Following the acid wash, the etched polycrystalline silicon powder is washed with water until the effluent is neutral. The resulting clean etched polycrystalline silicon powder is then dried at temperatures between about 30° C. to about 40° for about ten to twelve hours. Following drying the etched polycrystalline silicon powder has less than 1% moisture content and substantially all of the particles carry the silicon nanofibers described above and depicted in the scanning electron microscopy images of FIG. 1A and FIG. 1B.

The resulting polycrystalline silicon particles with silicon nanofibers, referred to herein as etched polycrystalline silicon particles, are particularly suited for use as an anode material in a lithium ion battery. The following discussion will describe one method for preparing an anode material from the etched polycrystalline silicon particles.

The described method begins by forming a mixture of the etched polycrystalline silicon particles with nano-particles of superconducting carbon and a carbon contributing precursor. Suitable liquid carbon contributing precursors include but are not limited to: citric acid, phenolic resin, mesophase pitch, 1-ethyl-3-methylimidazolium dicyanamide, acrylic acid, PEDOT:PSS, aniline monomer, polyacrylonitrile, resorcinol formaldehyde and furfuryl alcohol. The preferred precursor material is selected for its ability to yield at least 60% of its carbon content towards the formation of a carbonaceous coating on the etched polycrystalline silicon particles. For this reason, furfuryl is a particularly preferred precursor. The preferred superconducting carbon has a size range from about 5 nm to about 100 nm and a conductivity of about 2×10⁵ to about 4×10⁵ S/m and a purity of at least 90% with a preferred purity of about 97.5%.

The preparation of the mixture of etched polycrystalline silicon particles with superconducting carbon begins by initially de-agglomerating the superconducting carbon in a liquid dispersion media such as ethanol or acetone by sonication, stirring or vibration. Likewise, the etched polycrystalline silicon particles are de-agglomerated in a liquid dispersion media such as ethanol or acetone by sonication, stirring or vibration. Following de-agglomeration, evaporation of the liquid dispersion media and drying of the superconducting carbon and the etched polycrystalline silicon particles, the respective materials are added to the selected liquid carbon precursor material. The preferred liquid carbon precursor material is furfuryl alcohol.

After maintaining the dispersion of the etched polycrystalline silicon particles and superconducting carbon in the liquid carbon contributing precursor for about 10 minutes to about 60 minutes, HCl having a molarity of about 10 to about 15 is added to the dispersion. The volume of HCl necessary to produce the desired gel will vary with the amount of furfuryl alcohol and the temperature of the dispersion. In general, the amount of HCl may range from about 5 volume percent to about 80 volume percent. The addition of HCl causes at least a portion of the liquid carbon precursor material to form a gel on the surface of the etched polycrystalline silicon particles. The formation of the gel captures the superconducting carbon on the surface of the etched polycrystalline silicon particles and between the silicon nanofibers. The rate of gelation, i.e. polymerization of the liquid carbon precursor material, is influenced by temperature which may vary between 20° C. and 120° C. as well as the amount of HCl. Typically, the gelation process will take place over about 1 to about 60 minutes. The next step dries the gelled mixture at a temperature of about 80° C. to about 130° C. for a period of about two hours to about ten hours. The resulting dried etched polycrystalline silicon particles now carry an outer gel or polymer coating of precursor carbonaceous polymer derived from the carbon contributing precursor described above. The outer gel or polymer coating secures the superconducting carbon around the surface of the etched polycrystalline silicon particles thereby filling the gaps between the silicon nanofibers carried by the etched polycrystalline silicon particles. Thus the polymer coating covers the etched polycrystalline silicon particles and superconducting carbon to provide an anode precursor material having improved conductivity.

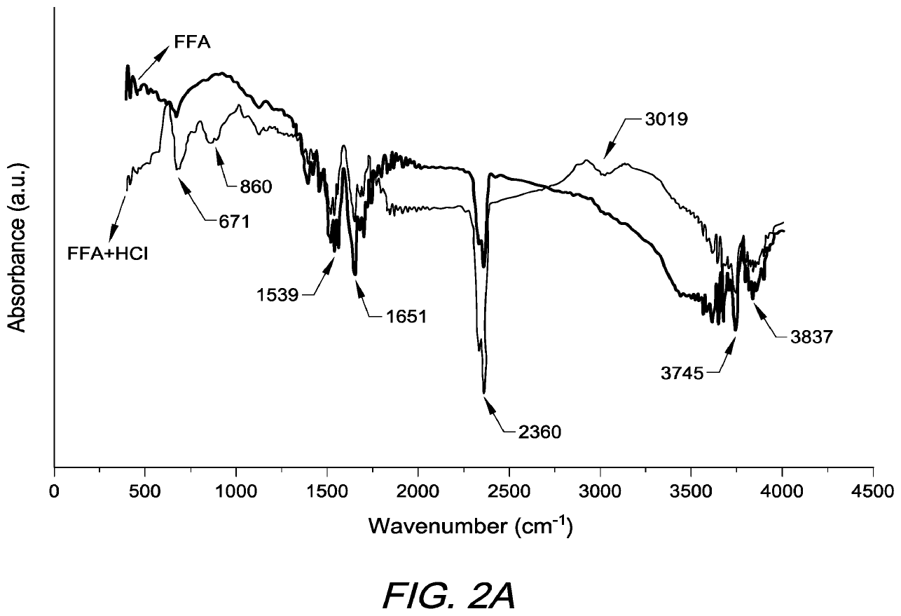

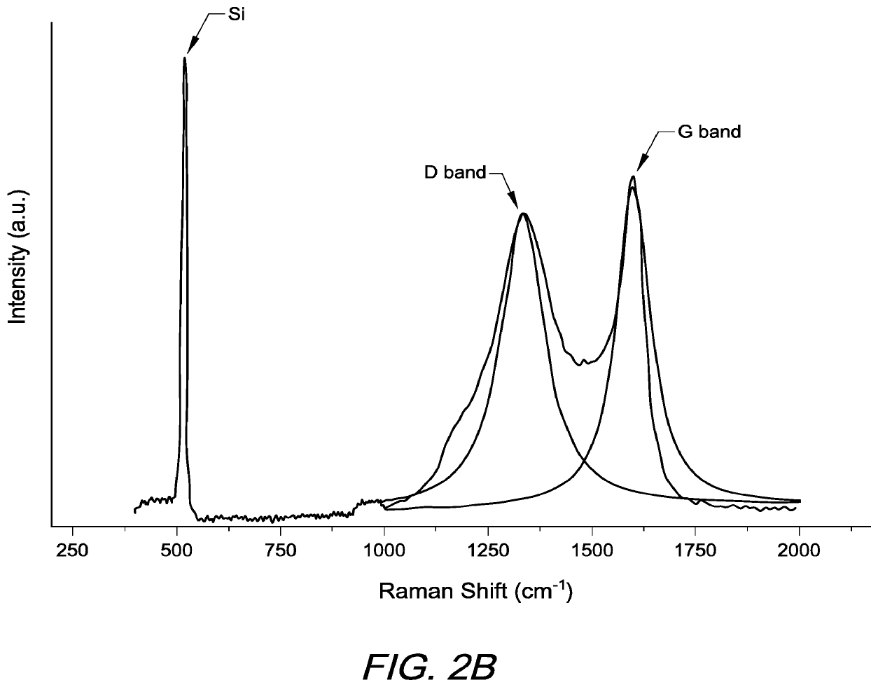

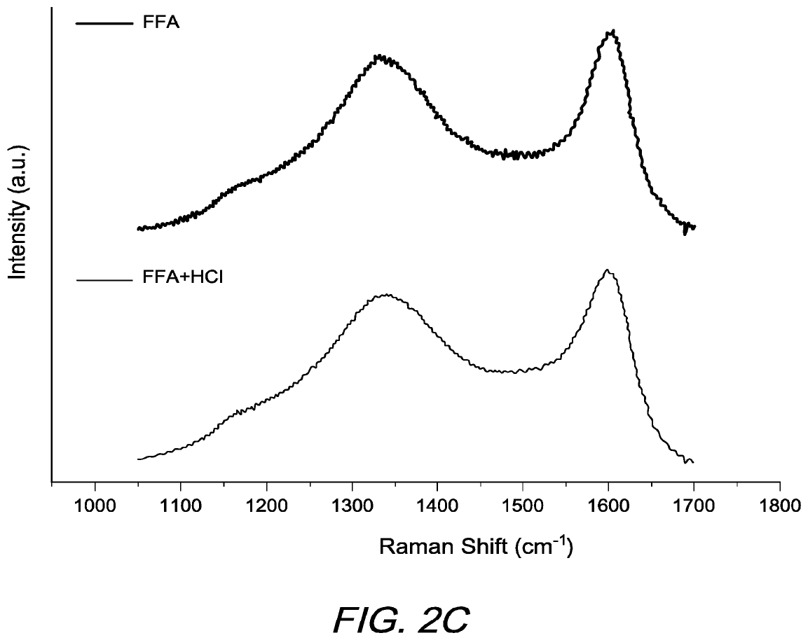

The resulting gel coat is characterized as a polymer derived from the liquid carbon contributing precursor used to suspend the superconducting carbon and the etched polycrystalline silicon particles. The FTIR scan provided in FIG. 2A demonstrates the advantage of using HCl in the gelation step. As depicted in the scan, the broad peaks appearing at 860 cm⁻¹ and 3019 cm⁻¹ in the scan of the gel coated etched polycrystalline silicon particles are indicative of improved polymerization of the carbon contributing precursor material. In this instance, the carbon contributing precursor was furfuryl alcohol (FFA). The Raman scan in FIG. 2C indicates that HC1 also reduces the amorphicity or defects in the final coated carbon and improves the polymerization process. The combined mass of carbon resulting from the carbon contributing precursor and the contributed mass from superconducting carbon in the final carbonaceous polymer coated product may vary from about 15% by weight to about 90% by weight.

To produce a conductive material suitable for use as an anode, the etched polycrystalline silicon particles with the carbonaceous polymer coating must be heated to convert the polymer to a conductive carbon coating. The heating process takes place in a furnace under an atmosphere that will not react with the heated materials in other words the atmosphere will not oxidize the materials. The process begins with the furnace at room temperature and progresses through two intermediate holding steps to a final internal furnace temperature of about 1100° C. Heating continues with the furnace operating at 1100° C. for about 60 minutes to about 180 minutes. The first hold temperature may be between about 550° C. and 650° C. with a preferred hold temperature of about 600° C. The second hold temperature may be between about 750° C. and 850° C. with a preferred hold temperature of about 800° C. The hold temperatures will be maintained for about 30 minutes to about 60 minutes. In general, the temperature can be increased at a rate of about 2° C. to about 20° C. per minute.

The heating step produces a uniform carbon-coating on the etched polycrystalline silicon particles. Thus, the resulting conductive material has a configuration wherein the silicon nanofibers are now networked, i.e. connected, and separated by superconducting carbon from the initial suspension and covered with a coating of conductive carbon derived from the liquid carbon contributing precursor material. In general, the carbon coating on the etched polycrystalline silicon particles may have a thickness of about 5 nm to about 100 nm. The preferred thickness of the carbon coating is from about 10 nm to about 50 nm. Preferably, the coating thickness should be sufficient to cover the entire surface of the etched polycrystalline silicon particles. The final thickness of the carbon coating may be controlled by increasing or decreasing the amount of the carbon contributing precursor used in the dispersion of the etched polycrystalline silicon particles and superconducting carbon. Additionally, variations in the viscosity of the resulting gel will influence the coating thickness. Viscosity of the gel is controlled by varying the gelation temperature and the amount of mineral acid used to produce the gel. As discussed above, the preferred mineral acid is HCl; however, nitric acid and sulfuric acid may also be used to produce the desired polymerization.

Thus, the resulting conductive material, contains etched polycrystalline silicon particles connected, and separated by superconducting carbon and has a coating of conductive carbon. The amount of silicon in the conductive material may vary from about 10% by weight to about 90% by weight. The preferred conductive material will have about 80% by weight silicon.

To prepare the desired anode structure, the conductive material is ground and combined with superconducting carbon. The blended material should have from about 0% by weight to about 10% by weight superconducting carbon. A binder solution of polyvinylidene fluoride in an organic solvent selected from the group consisting of: dimethyl sulfoxide and N-Methylpyrrolidine is prepared and added to the blend of superconducting carbon and the conductive material. A sufficient amount of the polyvinylidene fluoride solution is added to the blend of superconducting carbon and the conductive material to provide from about 2% by weight to about 20% by weight polyvinylidene fluoride in the final mixture. While polyvinylidene fluoride is a preferred binder material for securing the bonding between superconducting carbon and conductive material to one another and the metallic foil material of the anode, other suitable binder compounds for use in this step include but are not limited to: carboxymethylcellulose sodium (CMCNa), alginate, poly(acrylic acid) (PAA), styrene butadiene rubber (SBR), dopamine modified alginate, gum arabic, hyperbranched β-cyclodextrin polymer, guar gum, polyimide and polysaccharide.

The resulting slurry of polyvinylidene fluoride solution with the blend of superconducting carbon and the conductive material is mixed for a period of about six hours to about 24 hours. The final slurry can be used to produce an anode by coating the slurry onto a metallic foil support/current collector selected from the group consisting of: nickel and copper. Preferred metallic foil supports have a thickness of about 9 μm to about 20 μm. Following coating, the solvent is removed from the resulting paste by heating to a temperature sufficient to evolve the selected solvent. For example, when the polyvinylidene fluoride is dissolved in methylpyrrolidine, the drying step will take place at about 120° C. for a period of time sufficient to evolve all solvent. Following drying the coated metallic foil is pressed to provide a coating layer of uniform thickness on the metallic foil. The resulting metallic foil with a uniform coating of binder compound, superconducting carbon and conductive material can be cut to the desired size to form an anode half-cell.

While this invention is susceptible of embodiment in many different forms, there is shown in the drawings, and will herein be described hereinafter in detail, some specific embodiments of the instant invention. It should be understood, however, that the present disclosure is to be considered an exemplification of the principles of the invention and is not intended to limit the invention to the specific embodiments or algorithms so described.

### 1. Experimental

### 1.1 Materials Synthesis and Physicochemical Characterizations

One or more specific embodiments follow which are given for purposes of illustration only. These examples are not intended to be limiting with respect to the instant disclosure but, instead, are merely given as examples of the inventive techniques disclosed herein. Those of ordinary skill in the art will readily recognize how the specific examples and scenarios that follow could be generalized and applied.

Micron size polycrystalline Silicon powder (5-100 μm; metallurgical grade from global metallurgical Inc.) was first cleaned by acetone. After drying, the silicon powder (2.5 g) was dispersed in etchant solution containing, 0.15 g AgNO₃ (sigma Aldrich) in 25 ml of 4.6M hydrofluoric acid solution (40%, Sigma-Aldrich). Another solution comprised of 0.12M hydrogen peroxide (Sigma-Aldrich) was added drop wise into the previous rotating and uniformly premixed solution at an interval of 2-3 min for about 30 min. The whole mixture was then left for etching the micron size silicon particles at room temperature for 2 h to create Si nanofibers on the surfaces of the Si particles. The etching process was stopped by spraying deionized water and powder was separated by filtering from the solution. The filtered powder was soaked in nitric acid solution (65%, Sigma-Aldrich) for 20 min to remove the silver deposits on the etched particle surfaces and washed thoroughly using deionized water and separated successively using a centrifugation (VWR 13000 rpm, 15 min). This step was repeated for several times until the pH of the solution became neutral. Finally, the powder was dried on a hot plate before going for the next step of carbon coating. In few cases the silver deposits were reused instead of using new AgNO₃.

After etching, the etched silicon particles having nanofibers were mixed with superconducting carbon (US Research Nanomaterials, Inc.; size: 5-100 nm; conductivity: 2-4×105 S/m; purity: 97.5%) in 90:10 wt. ratio in furfuryl alcohol (FFA; 98% Acros organic) followed by de-agglomeration and separation of the two phases. After homogeneous and uniform mixing, the solution was suddenly gelled using HCl while rotating on a magnetic stirrer. The gelled sample was then dried at 100° C. for about 2 h. The polymer/gel coated sample thus created was kept inside a tubular furnace (Thermolyne Type 59300 High temperature Tube furnace) and the temperature was raised to 600° C. and after holding it for 1 h, the temperature was further increased to 750° C. at a constant heating rate of 5° C./min and held there for 2 h under continuous N₂ atmosphere to form a uniform carbon-coating on the etched silicon particles, which were networked and separated by the superconducting carbon. The thickness of the carbon coating was optimized by controlling the concentration of the polymer gel. Powder X-ray diffraction patterns were obtained using a Bruker AXS D8 X-ray diffractometer with CuK_{α} radiation between 10 and 90° (28 values). Field emission scanning electron microscopy (Hitachi S-4800) was used to analyze the images before and after coating the etched silicon particles. Fourier transform infrared (FTIR) spectra were acquired with an Agilent Varian 680-IR spectrometer with PIKE VeeMAX II in reflection mode using KBr powder in the range of 4000-400 cm⁻¹. Raman measurements were carried out using a Nicolet Almega XR Dispersive Raman 960 spectrometer with 532 nm laser excitation over the range 140-2000 cm-1 at 80% of incident laser power (max power: 150 mW). A collection time of 30 s was used for each spectrum and for each acquisition 20 spectra were accumulated in order to reduce noise and avoid CCD saturation. To analyze the Raman spectra, the peaks were fitted using ‘PeakFit’ software after linear background subtraction.

### 1.2 Electrode Preparation, Cell Assembly and Electrochemical Characterization

The coated material was ground and added with a small amount (2-5 wt. %) of superconducting carbon (97.5%, US Research Nanomaterials, Inc.) and 10 wt % of polyvinylidene fluoride (PVdF) in an N-Methylpyrrolidine (97%, sigma-aldrich) solution and mixed for overnight to make the slurry, which then was coated on a single sided polished copper foil (9 μm thick 99.99%, MTI Corp.). After drying the organic solvent at 120 ° C. using a hot plate for 10-15 min the coated foil was then transferred to a vacuum oven for storage. The coated foil was pressed using a laminating press to make a dense and uniformly thick electrode. The pressed electrode was cut into small pieces of 1 cm² to act as an anode for the half-cell. The electrochemical tests were performed in 2032 type coil cell with the laboratory made anode and Li metal (MTI Corp.) as the counter electrode inside an Ar-filled glovebox. The electrolyte used was 1.0 M LiPF₆ in 1:1 (w/w) ethylene carbonate/diethyl carbonate (Sigma-Aldrich). ‘Celgard’ separator was used for coin cells after soaking it in the electrolyte. Cyclic voltammetry measurements were conducted using a potentiostat (Princeton Applied Research, VersaSTAT 4) between 2V and 1 mV at a scan rate of 1 mV/sec. Electrochemical impedance spectroscopy measurements were also carried out using the same potentiostat used for cyclic voltametry measurements, between 1 MHz and 10 mHz. Battery cycling was performed using a MACCOR battery tester (4300 M). The voltage cutoff was set to 1.5 V and 1 mV versus Li/Li+, and the cycling current was set to 0.1 A for one gram of anode material (unless stated otherwise).

### 2. Results and Discussion

### 2.1 Coating on Hierarchical Nanostructures

The pristine micron size polycrystalline particles of silicon were etched using a modified metal assisted chemical etching method as described in experimental section. The resulting etched particles with silicon nanofibers are shown in FIG. 1.

After etching the porous regions surrounding the nanofibers on silicon particles were filled and separated by superconducting carbon. The mixture was then uniformly dispersed in furfuryl alcohol (FFA) with or without HCl to polymerize and suddenly gel the structure. To check the effect of extra polymerizing agent, the sample was characterized using FTIR. FIG. 2A shows the FTIR spectra of the furfuryl alcohol coated etched silicon particles along with the spectra taken on the similarly processed coated particles but after extra polymerizing agent HCL The advantage of using HCl to get a well graphitized carbon is indicated from FIG. 2C, where it can be clearly observed that without HCl the level of graphitization is less as indicated by the ratio R (˜0.95; R=I_{d}/I_{g}, where I_{d} is the intensity from the defect band of sp3 bonding and I_{g} is the intensity from the graphitic band or sp2 bonding). The meaning of lower values of R (˜0.79) could be either the intensity coming from the defect band is less or intensity coming from the graphitic band is more. In both ways, it's an indication of the presence of well-graphitized carbon, which can be observed when HCl was used as a polymerizing agent to get a carbon coating. The appearance and broadening of extra FTIR peaks at 860 and 3019 cm⁻¹ are indicative of more polymerization, whereas, without HCl, the polymerization was incomplete (FIG. 2A). It is well known that the level of polymerization helps in sp2 bond formation. Thus, after carbonization, the sample coated with the help of HCl in addition to FFA gives better graphitization as can be seen from FIG. 2C. We have optimized the temperature of carbonization (750° C.) as it can have direct implication to the level of graphitization. FIG. 2B, shows the Raman spectra taken on the FFA+HCl coated etched silicon particles. The overall higher intensity of the peak coming from silicon at −522 cm-1 indicates that most of the underlying material is still silicon and lesser amount of carbonaceous material is as a thin coating. The strong presence of the peaks associated with the carbonaceous phase indicates that the quality and uniform coverage of the carbon coating is achieved. It should be mentioned that Raman spectroscopy is a surface sensitive characterization technique and thus, the peak intensity coming from the carbonaceous phase is strong enough although less than the peak intensity coming from the underlying silicon. The presence of D band and G bands alone can be distinguished after deconvolution of the observed peak. The presence of the D band located at −1334 cm⁻¹ and the G band, which appears at −1598 cm⁻¹ can be distinguished after deconvolution of the observed peak (FIG. 2B).

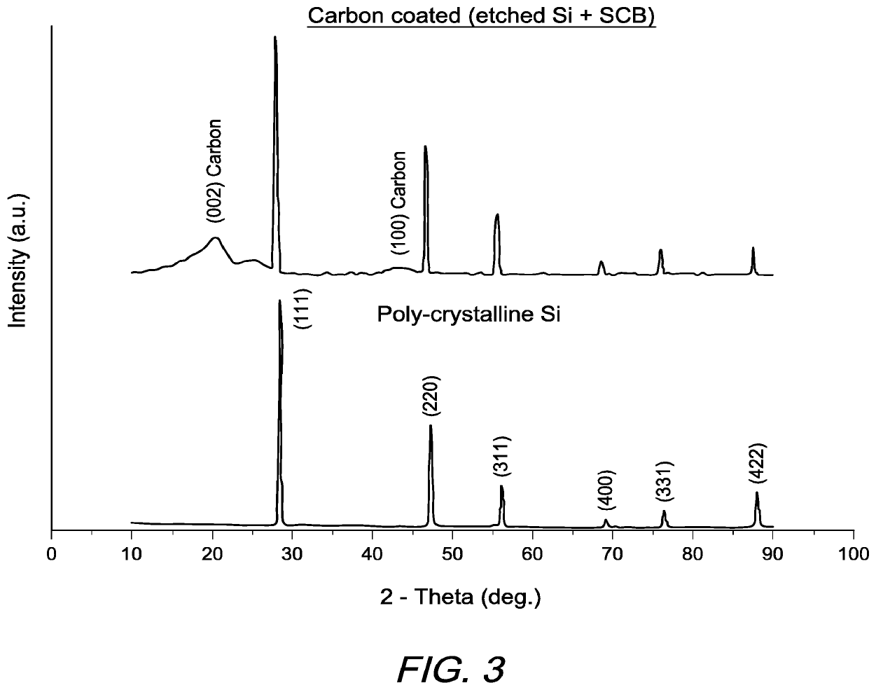

Further, the XRD patterns taken from the raw polycrystalline silicon powder vs. XRD pattern taken from FFA+HCl derived carbon coated sample show the majority of the peaks coming from silicon along with the presence of graphitic carbon (FIG. 3).

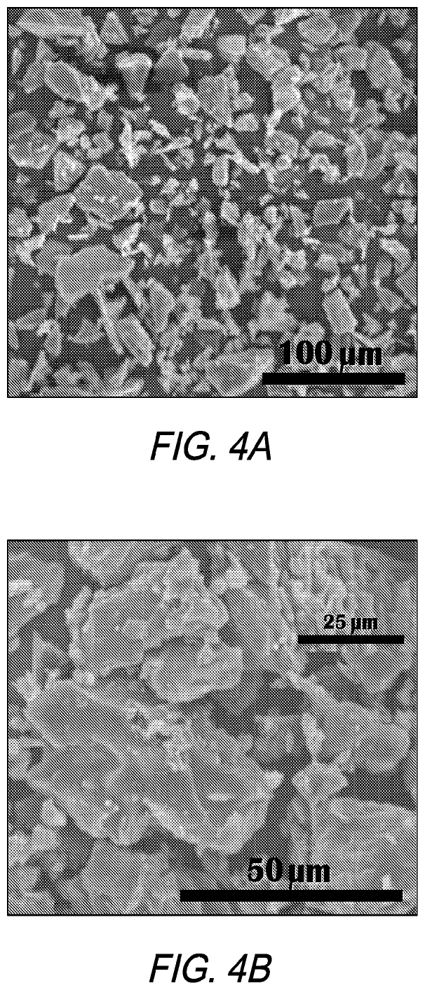

Carbon coated etched silicon powders filled and separated with superconducting carbon are shown in FIG. 4. The uniformity of coating on each particle without agglomeration can be observed from FIG. 4A. The coated surface looks smooth with some roughened areas and pores (FIG. 4B), which may come from the porous structure although it was filled with superconducting carbon before coating. The thickness of the coating can be visually recognized by the step heights within the nanofibers. Overall FIG. 4 shows the addition of 5-10 wt. % superconducting phase of superconducting carbon with varied size was not only able to fill up the void regions between the silicon nanofibers but also stayed outside the etched particles during solution polymerization to avoid agglomeration. Thus, we could achieve the coating on individual etched particles, which is one of the major challenges for coating on each and every particle, especially inside the electrode materials.

### 2.2 Electrochemical Performance

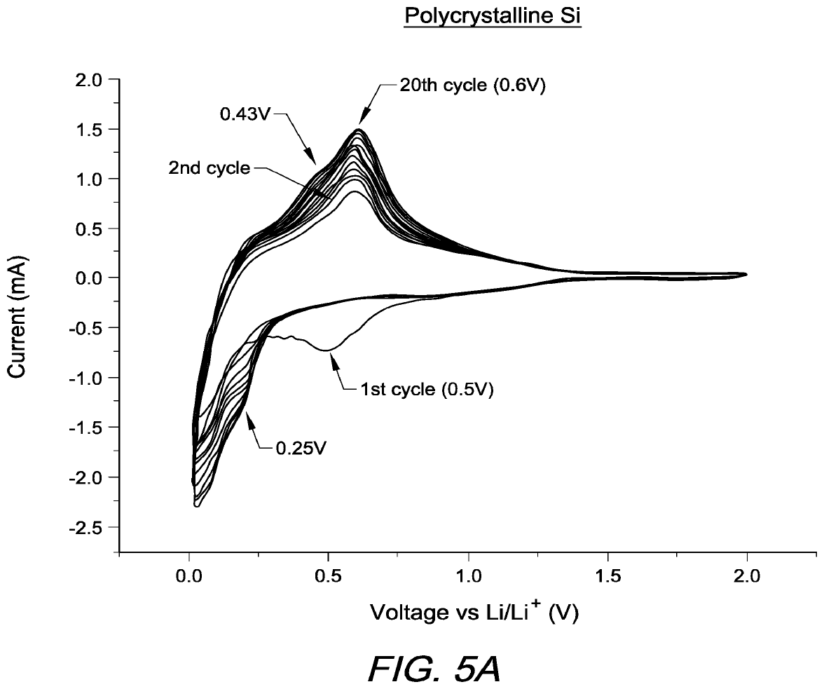

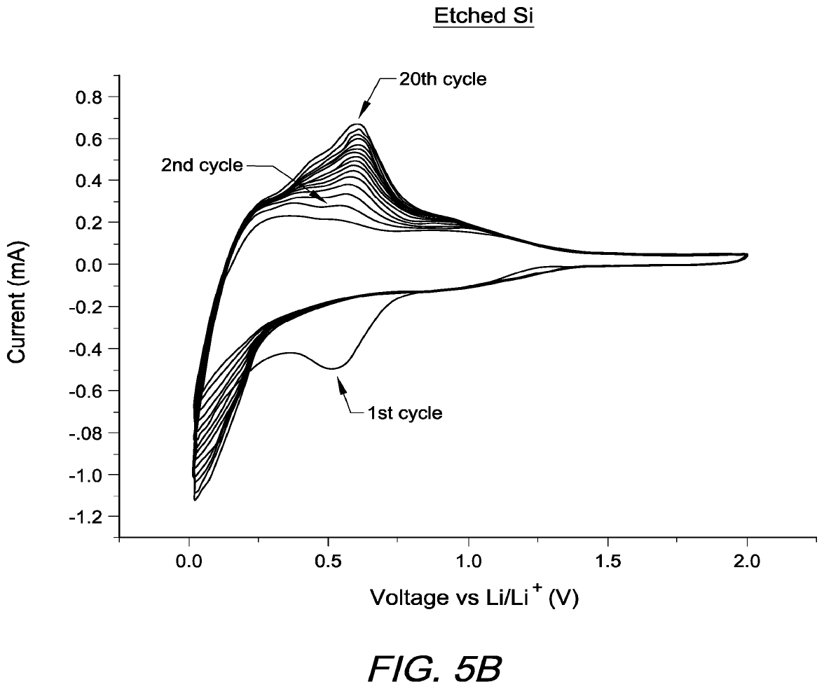

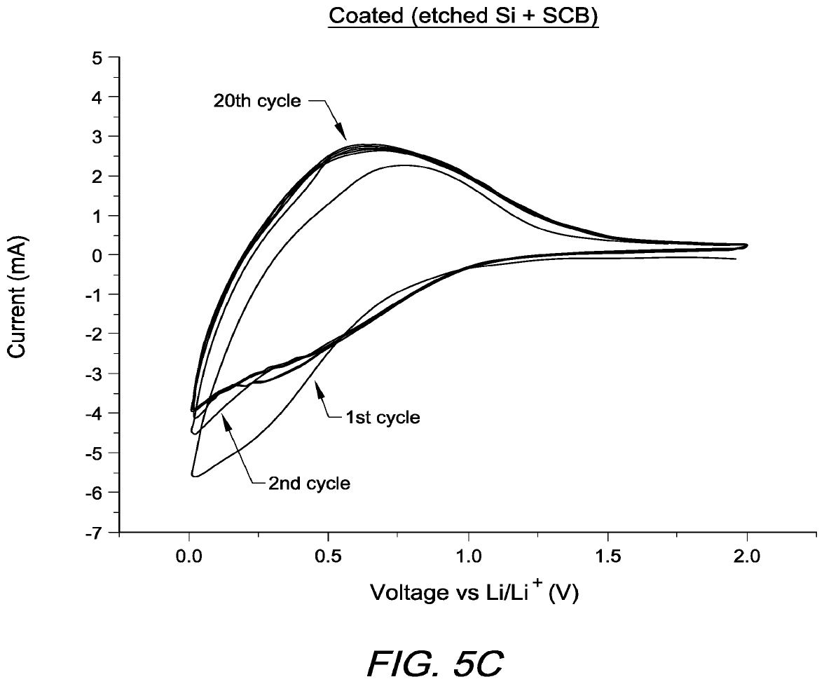

The electrochemical behavior was first analyzed by cyclic voltammetry. The broad peak at ˜0.5V, during first cycle lithiation of pristine polycrystalline silicon is related to formation of the solid electrolyte interphase (SEI) due to reaction with the electrolyte and active silicon material (FIG. 5A). It should be noted that the peak due to SEI formation is also present at almost the same potential value for the etched silicon particles (FIG. 5B). However, it suddenly disappeared from the sample when it is filled and coated with carbonaceous material (FIG. 5C). It should be noted that by filling the void spaces between the silicon nanofibers and coating with carbon reduces the overall surface area and hence the amount of SEI, because SEI formation is a surface area dependent reaction. It should also be noted that in this case reducing the surface area will only reduce the formation of SEI but will not interfere or hinder the number of lithium ions to intercalate. Since the graphitic layer itself it should be a stable host for lithium ions and has the ability to intercalate and de-intercalate lithium ion reversibly. Thus, all the carbon structures inside and outside will allow lithium to diffuse inside to enter into the silicon lattice and the high surface areas created by etching and from the silicon nanofibers will be available for intercalation.

Cyclic voltammetry curves of the (a) pristine polycrystalline silicon, (b) etched porous silicon and (c) coated and etched silicon filled with SCB. The appearance of a broad shoulder at ˜0.2 5V in FIG. 5A is probably due to the formation of metastable Li-rich clusters, which forms within the amorphous lithium-silicon alloy (a-LiₓSi), and is absent in both FIGS. 5B and 5C. The absence of the peak could be due to the presence of nanostructured silicon. Further it should be mentioned that any metastable phase formation during lithiation process i s known to have detrimental effect in capacity retention. Thus, avoiding this metastable phase during lithiation of crystalline silicon leads to better cyclability as verified later. The absence of any peak at 0.5 or 0.25V in etched and coated samples is due to the modified hierarchical nanostructures created by the carbon coating as well as the presence of silicon nanofibers as discussed earlier. However, for all the samples and for all the cycles of lithiation the sharp intense peak centered at ˜0.0 1V corresponds to the complete alloying reaction between silicon and lithium. The anodic reactions in both FIGS. 5A & 5B, show one broad shoulder centered at 0.43V and one peak centered at 0.6V, ascribed to the delithiation from LiₓSi. The reproducibility of the coated sample can be related to the overlapping of the de-alloying curves as is clearly evident from FIG. 5C.

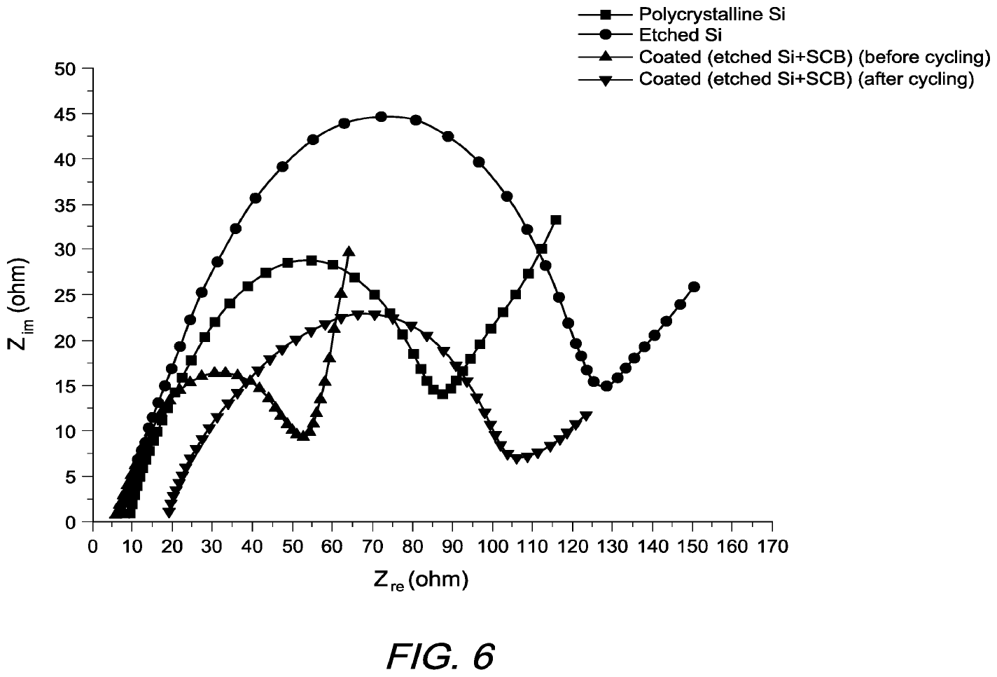

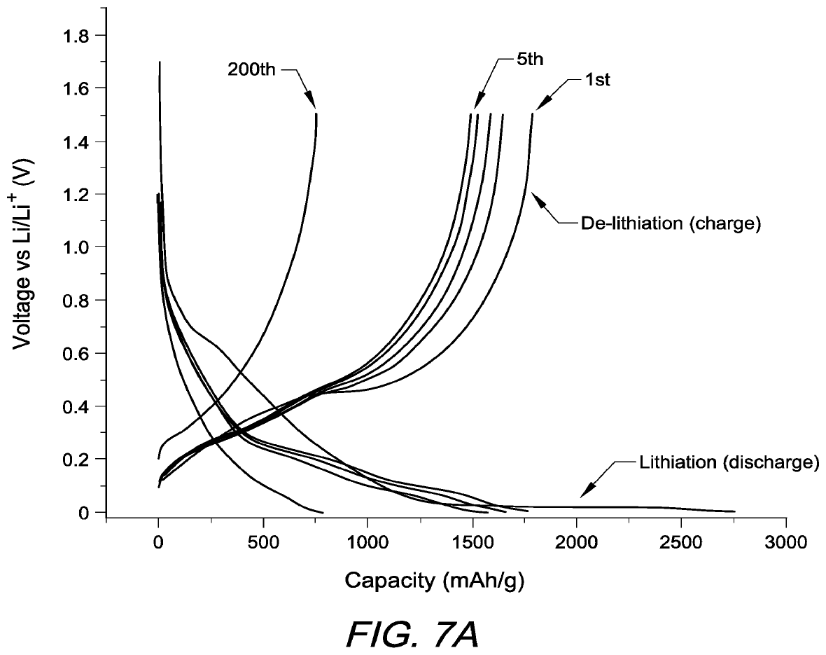

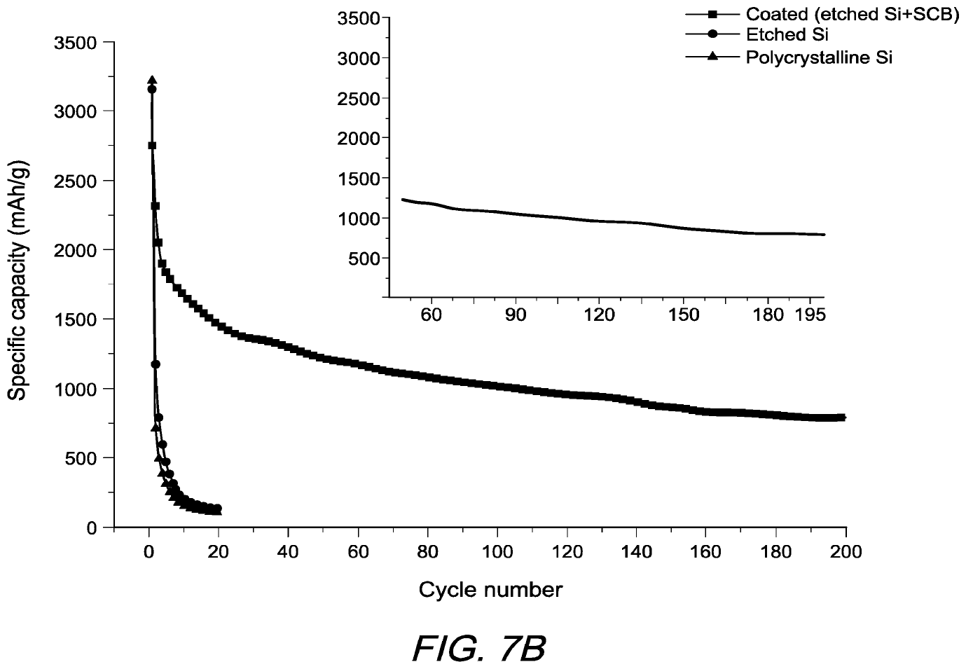

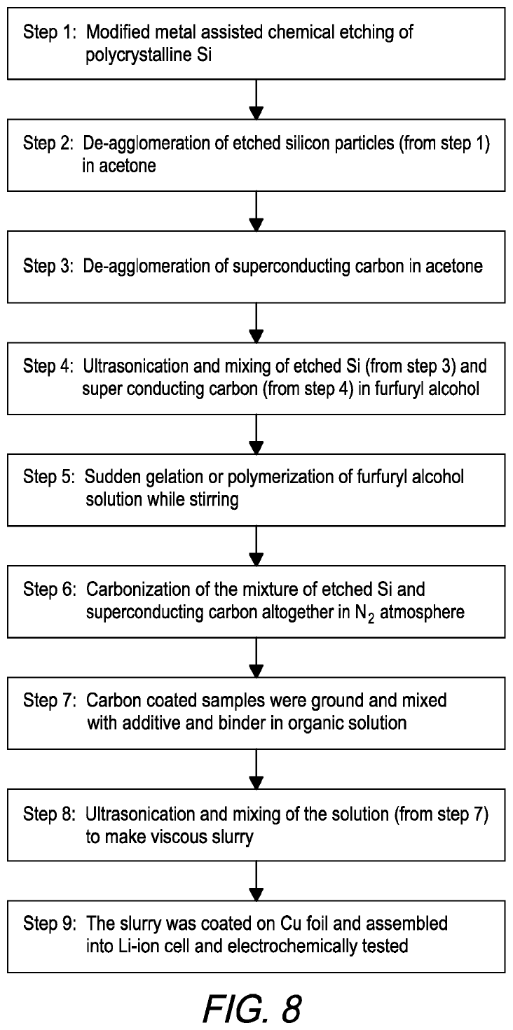

The electrochemical impedance spectroscopy (EIS) curves for the etched and coated samples before cycling and after 200 cycles are shown in FIG. 6 along with the curves for as-received silicon and etched silicon. The resistive components (R_{C}, R_{S}, and R_{E}) calculated from the intercepts of the semicircle are given in Table 1. Where R_{C} is the contact resistance between electrode and copper substrate/current collector, and R_{S} is the total resistance of the electrode and copper substrate/current collector, and R_{E}=R_{S}−R_{C} is the effective electrode resistance. The increase in resistance of the etched silicon sample in comparison to the as-received silicon is probably due to more SEI layer formation on the silicon nanofibers created by etching. But modification of the similar etched sample by carbon coating results in much lower resistance (R_{E} of 64.8 Vs 131.5 ohm) by a factor of almost 2. This lowering of resistance could be due to the uniform SEI formation from carbon overcoat. However, after 200 cycles of the same coated sample resulted in larger semicircle than before cycling. Both R_{C} and R_{S} values increased after 200 cycles indicating higher contact resistance from the substrate as well as from bulk of the electrode. This could be due to the fracture of core silicon particles, especially large size particles, where even after etching the materials was not converted to fully nanostructured silicon. However, the resistance is still less than the resistance of the etched silicon electrode alone, even after 200 cycles as can be seen from Table 1 and FIG. 6. Thus, this new way of processing helps in improving the total conductivity of the cell and also provides stability of the active material against lithiation and delithiation, which results in high reversible capacity even after 200 cycles (FIG. 7B). Increased contact resistance from the copper substrate may have also contributed to capacity loss. Further optimization of the electrodes and associated assembly by lowering resistance is expected to further decrease in capacity loss.

TABLE 1
Calculated electrode resistance from the Nyquist plots.

| | Contact | Total | Net Electrode |
|---|---|---|---|
| | Resistance, | Resistance, | Resistance, |
| Sample | R_{C} (ohm) | R_{S} (ohm) | R_{E} (ohm) |
| Polycrystalline Si | 5.9 | 101.8 | 95.9 |
| Etched Si | 5.9 | 137.4 | 131.5 |
| Modified Sample | 4.5 | 69.3 | 64.8 |
| Before cycling | | | |
| Modified sample | 17.7 | 113 | 95.3 |
| after 200 cycles | | | |

Charge-discharge curves for the modified samples are shown in FIG. 7A along with the curves for as-received polycrystalline and etched silicon samples. The highest lithiation capacity of ˜3214 mAh/g was observed for the as-received silicon sample in first cycle. However, for the modified/coated sample, the first lithiation cycle (discharge) specific capacity of ˜2750 mAh/g is obtained. The high initial specific capacity is an indication of major participation of silicon within the carbonaceous network. The subsequent charge/discharge cycles maintained improved coulombic efficiency (99.6%) with a reversible capacity of ˜778 mAh/g even after 200 cycles. This high reversible capacity with very high coulombic efficiency are among the best values reported for silicon-based composite anodes. The modified/coated electrode structure shows improved cyclability, when compared to as-received silicon sample or etched alone silicon sample, which have lost all their capacity even after 15-20 cycles. The worse cycle life in terms of capacity fading for the unetched and uncoated samples (made conventionally) is probably due to the fracture and detachment from each other and from the current collector as well. It should be remembered that in conventional approach, we have not followed the steps for avoiding agglomeration and coating. The modified/coated sample was processed by gelling (suddenly) the mixture of superconducting carbon and etched silicon in polymeric solution, which created electrically well-connected nanostructure electrode. Upon firing, the frozen polymeric gel produced interconnected carbon coating on individually etched particles. The failure of as-received polycrystalline sample is quite obvious due to its fracture, which is unavoidable for the large micron size Si particles. Even after etching, the sample failed probably due to the isolation caused by the fracture from the un-etched core silicon.

The improved performance and capacity retention of the modified/coated sample can be attributed to the newly adopted processing of the electrode. In this approach, a uniform electrical connectivity was achieved by the SCB and carbon coating during the processing step in which rapid gelation of the FFA by HNO₃ created the uniformly mixed individual phases in the electrode. The porous structure filled and separated by SCB and then coated with thin layers of carbon improved the stability of SEI layer formation, which could also decrease the capacity loss. The absence of obvious peak due to SEI formation can be inferred from the cyclic voltammetry (FIG. 5C). This may be an indication of a more uniform SEI layer formation. The controlled and uniform SEI layer can also contribute to improved reversible capacity. A long and gradual increase in the slope starting at ˜0.1V (FIG. 7A, 1st lithiation cycle) is characteristic of alloying reaction between lithium and host silicon matrix. Subsequent lithiation curves show a slope starting at ˜0.3V (FIG. 7A, 2nd cycle onwards), probably as a result of lithiation of the amorphous silicon. FIG. 7B shows improved reversible capacity with high coulombic efficiency, especially after a few initial cycles. The improvement in capacity retention can be clearly observed from the relatively flat nature of the curve, when plotted between 50 and 200 cycles (inset of FIG. 7B).

The particular approach disclosed herein in connection with one embodiment ensures that the pores or voids available between the etched silicon particles are filled with different shape and size of the superconducting carbon. This may provide the conducting path even after fracture of Si thereby enhancing the conductivity of the active anode materials, which is required for getting high discharge capacity even after many number of cycles. Not only that, the conformal and uniform conducting carbon coating on individual particles, which is achieved by avoiding agglomeration during previous step of gelation also provides a stable and flexible cover. This approach also controls the amount of SEI formation without which there would have been a successive loss in capacity when the silicon particles fracture and create new surfaces for additional formation of the SEI layer. The presence of enhanced number of reversible sites for intercalation in carbon-based anode materials also depends on the level of graphitization. It has been reported that increased defects result in increased irreversible capacity by providing more sites for lithium ions. The lower value of the ratio I_{d}/I_{g} in Raman spectra of our study also indicates formation of more graphitic phase in the coating thereby facilitating easy path through the graphitic layer of lithium towards silicon anode during lithiation and de-lithiation steps.

### 3. Conclusions:

A embodiment of a cost-effective method of processing hierarchical nanostructured porous silicon electrode interlinked and filled with highly conducting phase is taught herein. This approach helps ensure that the network containing porous structure is filled with and separated by superconducting carbon and covered with a conformal and uniform conducting coating for achieving superior performance. The structure not only enhances the structural stability but also provides conductive path even after fracture of Si by the interlinked superconducting phase and outer layer of carbon coating. Some major conclusions of various embodiments include:
1. The new way of processing provides channels for fast electronic and ionic transfer, as well as free space for relaxation during volume expansion.
2. An embodiment of this processing approach also helps in avoiding agglomeration of particles (by sudden gelation), which is a primary obstacle for coating individual particles.
3. Controlled SEI formation kinetics in sample coated with carbon was achieved as indicated by the absence of obvious SEI peak for silicon at 0.5 V.
4. The EIS results show the improvement in the overall conductivity, which helped in getting high reversible capacity.
5. The materials processed in this way show an impressive specific capacity of approximately 1018 mAh/g after 100 cycles and the capacity remains ˜778 mAh/g even after 200 cycles with a very high coulombic efficiency of 99.6%.

Additional advantages of different embodiments might include:
Low cost manufacturing of anode using metallurgical low grade polycrystalline silicon and furfuryl alcohol. Also, silicon itself is a second most abundant material in the earth.
High r eversible capacity (up to 1100 after 100 cycles) could be potentially exploited from coin cell to high capacity electric vehicle, to reduce greenhouse gas emission and proper use of renewable energy by storing them into high capacity batteries.
Can be used to miniaturize the storage device or very high energy capacity batteries.
Highly uniform and homogeneous coating on current collector (Cu) can be achieved which is a prerequisite factor for any good quality electrode.
Uses very robust and compatible technique to practice of manufacturing electrode starting from easy to scale up technique of etching particles, mixing and making slurry for coating electrode foil.

It is to be understood that the terms “including”, “comprising”, “consisting” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not to be construed that there is only one of that element.

It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The term “method” may refer to manners, means, techniques and procedures for accomplishing a given task including, but not limited to, those manners, means, techniques and procedures either known to, or readily developed from known manners, means, techniques and procedures by practitioners of the art to which the invention belongs.

For purposes of the instant disclosure, the term “at least” followed by a number is used herein to denote the start of a range beginning with that number (which may be a ranger having an upper limit or no upper limit, depending on the variable being defined). For example, “at least 1” means 1 or more than 1. The term “at most” followed by a number is used herein to denote the end of a range ending with that number (which may be a range having 1 or 0 as its lower limit, or a range having no lower limit, depending upon the variable being defined). For example, “at most 4” means 4 or less than 4, and “at most 40%” means 40% or less than 40%. Terms of approximation (e.g., “about”, “substantially”, “approximately”, etc.) should be interpreted according to their ordinary and customary meanings as used in the associated art unless indicated otherwise. Absent a specific definition and absent ordinary and customary usage in the associated art, such terms should be interpreted to be±10% of the base value.

When, in this document, a range is given as “(a first number) to (a second number)” or “(a first number)-(a second number)”, this means a range whose lower limit is the first number and whose upper limit is the second number. For example, 25 to 100 should be interpreted to mean a range whose lower limit is 25 and whose upper limit is 100. Additionally, it should be noted that where a range is given, every possible subrange or interval within that range is also specifically intended unless the context indicates to the contrary. For example, if the specification indicates a range of 25 to 100 such range is also intended to include subranges such as 26-100, 27-100, etc., 25-99, 25-98, etc., as well as any other possible combination of lower and upper values within the stated range, e.g., 33-47, 60-97, 41-45, 28-96, etc. Note that integer range values have been used in this paragraph for purposes of illustration only and decimal and fractional values (e.g., 46.7-91.3) should also be understood to be intended as possible subrange endpoints unless specifically excluded.

It should be noted that where reference is made herein to a method comprising two or more defined steps, the defined steps can be carried out in any order or simultaneously (except where context excludes that possibility), and the method can also include one or more other steps which are carried out before any of the defined steps, between two of the defined steps, or after all of the defined steps (except where context excludes that possibility).

Further, it should be noted that terms of approximation (e.g., “about”, “substantially”, “approximately”, etc.) are to be interpreted according to their ordinary and customary meanings as used in the associated art unless indicated otherwise herein. Absent a specific definition within this disclosure, and absent ordinary and customary usage in the associated art, such terms should be interpreted to be pius or minus 10% of the base value.

Still further, additional aspects of the instant invention may be found in one or more appendices attached hereto and/or filed herewith, the disclosures of which are incorporated herein by reference as if fully set out at this point.

Thus, the present invention is well adapted to carry out the objects and attain the ends and advantages mentioned above as well as those inherent therein. While the inventive device has been described and illustrated herein by reference to certain preferred embodiments in relation to the drawings attached thereto, various changes and further modifications, apart from those shown or suggested herein, may be made therein by those of ordinary skill in the art, without departing from the spirit of the inventive concept the scope of which is to be determined by the following claims.

We claim:

1. A method for preparing silicon particles carrying silicon nanofibers comprising:
providing micron sized polycrystalline silicon powder;
preparing an etchant solution of silver nitrate in hydrofluoric acid;
forming a dispersion by dispersing said micron sized polycrystalline silicon powder in said etchant solution;
adding hydrogen peroxide to said dispersion of micron sized polycrystalline silicon powder in said etchant solution;
after allowing sufficient time to etch said polycrystalline silicon powder, neutralize said dispersion by addition of a neutralizing agent;
isolate the resulting etched polycrystalline silicon powder.

2. The method of claim 1, wherein said micron sized polycrystalline silicon powder has particle sizes between about 1 μm and 300 μm.

3. The method of claim 1, wherein said etchant solution of silver nitrate in hydrofluoric acid contains from about 2% to about 6% by weight silver nitrate.

4. The method of claim 1, wherein the hydrofluoric acid of said etchant solution of silver nitrate in hydrofluoric acid has a molarity of about 4 to about 6.

5. The method of claim 1, wherein said dispersion of said micron sized polycrystalline silicon powder in said etchant solution has from about 94% to about 98% by weight said micron sized polycrystalline silicon powder.

6. The method of claim 1, wherein said hydrogen peroxide has a molarity of about 0.1 to about 0.8.

7. The method of claim 1, wherein said step of adding hydrogen peroxide continues until the resulting mixture contains from about 1% to about 3% by volume of hydrogen peroxide.

8. The method of claim 1, wherein said step of allowing sufficient time to etch said polycrystalline silicon powder continues with agitation for a period of about two to five hours for every 2.5 gram of polycrystalline silicon powder in said dispersion.

9. The method of claim 1, further comprising the steps:
washing said etched polycrystalline silicon powder with a mineral acid or a mixture of mineral acids, said mineral acid or mixture of mineral acids selected to provide the ability to remove any trace amounts of silver on said etched polycrystalline silicon powder.

10. The method of claim 9, further comprising the step of washing said etched polycrystalline silicon powder with water until the effluent of said washing step is neutral.

11. The method of claim 10, further comprising the step of drying said etched polycrystalline silicon powder until said etched polycrystalline silicon powder has a moisture content of less than 1%.

12. The method of claim 11, wherein said drying step takes place at temperatures between about 30° C. to about 40° for about ten to twelve hours.

13. An etched polycrystalline silicon particle comprising:
a polycrystalline silicon particle having a size between about 1 μm and about 300 μm;
a plurality of silicon nanofibers carried by the surface of said polycrystalline silicon particle, said silicon nanofibers having a length of about 500 nm to about 20 μm.

14. The etched polycrystalline silicon particle of claim 13, wherein said silicon nanofibers have a diameter of about 30 nm to about 100 nm.

15. The etched polycrystalline silicon particle of claim 13, wherein said silicon nanofibers have a separation gap from one another of about 50 nm to about

16. An etched polycrystalline silicon particle comprising:
a polycrystalline silicon particle having a size between about 1 μm and about 300 μm;
a plurality of silicon nanofibers carried by the surface of said polycrystalline silicon particle, said silicon nanofibers have a diameter of about 30 nm to about 100 nm.

17. The etched polycrystalline silicon particle of claim 16, wherein said silicon nanofibers having a length of about 500 nm to about 20 μm.

18. The etched polycrystalline silicon particle of claim 16, wherein said silicon nanofibers have a separation gap from one another of about 50 nm to about

19. An etched polycrystalline silicon particle comprising:
a polycrystalline silicon particle having a size between about 1 μm and about 300 μm;
a plurality of silicon nanofibers carried by the surface of said polycrystalline silicon particle, wherein said silicon nanofibers have a separation gap from one another of about 50 nm to about

20. A method for preparing an anode material comprising the steps:
providing etched polycrystalline silicon particles;
providing superconducting carbon;
providing a liquid carbon contributing precursor;
blending said etched polycrystalline silicon particles with said superconducting carbon and said liquid carbon contributing precursor to form a mixture;
forming a polymer coating on said etched polycrystalline silicon particles by adding HCl to said mixture of etched polycrystalline silicon particles, superconducting carbon and said liquid carbon contributing precursor;
providing a conductive material by heating said etched polycrystalline silicon particles carrying said polymer coating to convert said polymer coating to a conductive carbon coating having a thickness of about 10 nm to about 50 nm;
grind said conductive material and combine with superconducting carbon to form a blended material;
form a slurry by adding a binder solution to said blended material of superconducting carbon and conductive material;
coating said slurry onto a metallic foil suitable for use as an anode thereby providing a layer of said slurry on said metallic foil;
removing solvent from slurry by heating; and,
forming said metallic foil with said layer of said slurry into an anode.

21. The method of claim 20, wherein said liquid carbon contributing precursors are selected from the group consisting of: citric acid, phenolic resin, mesophase pitch, 1-ethyl-3-methylimidazolium dicyanamide, acrylic acid, PEDOT:PSS, aniline monomer, polyacrylonitrile, resorcinol formaldehyde and furfuryl alcohol and blends thereof.

22. The method of claim 20, wherein said superconducting carbon has a size range from about 5nm to about 100nm.

23. The method of claim 20, wherein said superconducting carbon has a conductivity of about 2×10⁵ to about 4×10⁵ S/m.

24. The method of claim 20, wherein said superconducting carbon has a purity of at least 90%.

25. The method of claim 20, wherein said step of forming a carbonaceous polymer coating takes place at a temperature between about 20° C. and 120° C.

26. The method of claim 20, wherein said step of forming a carbonaceous polymer coating takes place at a temperature between about 20° C. and 120° C. and over a time period of about 1 minute to about 60 minutes.

27. The method of claim 20, wherein said step of providing a conductive material by heating said etched polycrystalline silicon particles carrying said carbonaceous polymer coating to convert said carbonaceous polymer coating to a conductive carbon coating having a thickness of about 10 nm to about 50 nm takes place within a furnace operating at a temperature of about 1100° C.

28. The method of claim 21, wherein said step of heating begins at room temperature and increases to a first hold temperature between about 550° C. and 650° C. and maintained at said first hold temperature for a period of about 30 to 60 minutes followed by an increase in temperature to a second hold temperature between about 750° C. and 850° and maintained at said second hold temperature for a period of about 30 to 60 minutes followed by an increase in temperature to 1100° C. for a period of about 60 to 180 minutes.

29. The method of claim 20, wherein said binder solution is prepared from an organic solvent selected from the group consisting of: dimethyl sulfoxide and N-Methylpyrrolidine and mixtures thereof; and,
a binder material selected from the group consisting of: carboxymethylcellulose sodium (CMCNa), alginate, poly(acrylic acid) (PAA), styrene butadiene rubber (SBR), dopamine modified alginate, gum arabic, hyperbranched β-cyclodextrin polymer, guar gum, polyimide, polysaccharide and polyvinylidene fluoride.

30. A conductive material comprising:
etched polycrystalline silicon particles carrying silicon nanofibers;
a polymer coating carried on the surface of said etched polycrystalline silicon particles, said polymer coating bridging the gaps between said silicon nanofibers and having a thickness of about 5 nm to about 100 nm.

31. The conductive material of claim 30, wherein said polycrystalline silicon particles are from 10% by weight to 90% by weight of said conductive material.

32. The conductive material of claim 30, wherein said polycrystalline silicon particles are from 75% by weight to 85% by weight of said conductive material.

33. The conductive material of claim 30, wherein said silicon nanofibers have a diameter of about 30 nm to about 100 nm.

34. The conductive material of claim 30, wherein said silicon nanofibers having a length of about 500 nm to about 20 μm.

35. The conductive material of claim 30, wherein said silicon nanofibers have a separation gap from one another of about 50 nm to about

36. The conductive material of claim 30, further comprising super conducting carbon particle around said etched polycrystalline silicon particles and filling the gaps between said silicon nanofibers.

37. A conductive material comprising:
etched polycrystalline silicon particles carrying silicon nanofibers, said silicon nanofibers separated from one another by a gap of about 50 nm to about 1 μm;
superconducting carbon particles on the surface of said etched polycrystalline silicon particles and in said gaps between said silicon nanofibers;
a polymer coating over said etched polycrystalline silicon particles and said superconducting nanoparticles, said polymer coating having a thickness of about 5 nm to about 100 nm.

38. The conductive material of claim 37, wherein said polycrystalline silicon particles are from 10% by weight to 90% by weight of said conductive material.

39. The conductive material of claim 37, wherein said polycrystalline silicon particles are from 75% by weight to 85% by weight of said conductive material.

40. The conductive material of claim 37, wherein said silicon nanofibers have a diameter of about 30 nm to about 100 nm.

41. The conductive material of claim 37, wherein said silicon nanofibers having a length of about 500 nm to about 20 μm.

42. An anode comprising:
etched polycrystalline silicon particles carrying silicon nanofibers, said silicon nanofibers separated from one another by a gap of about 50 nm to about 1 μm;
superconducting carbon particles on the surface of said etched polycrystalline silicon particles and in said gaps between said silicon nanofibers;
a polymer coating over said etched polycrystalline silicon particles and said superconducting nanoparticles, said polymer coating having a thickness of about 5 nm to about 100 nm;
a binder compound; and,
a metal support;
said anode having a specific capacity of at least 1000 mAh/g after 100 cycles.

43. An anode comprising:
etched polycrystalline silicon particles carrying silicon nanofibers, said silicon nanofibers separated from one another by a gap of about 50 nm to about 1 μm;
superconducting carbon particles on the surface of said etched polycrystalline silicon particles and in said gaps between said silicon nanofibers;
a polymer coating over said etched polycrystalline silicon particles and said superconducting nanoparticles, said polymer coating having a thickness of about 5 nm to about 100 nm;
a binder compound; and,
a metal support;
said anode having a specific capacity of at least 770 mAh/g after 200 cycles.

44. An anode comprising:
etched polycrystalline silicon particles carrying silicon nanofibers, said silicon nanofibers separated from one another by a gap of about 50 nm to about 1 μm;
superconducting carbon particles on the surface of said etched polycrystalline silicon particles and in said gaps between said silicon nanofibers;
a polymer coating over said etched polycrystalline silicon particles and said superconducting nanoparticles, said polymer coating having a thickness of about 5 nm to about 100 nm;
a binder compound; and,
a metal support;
said anode having a coulombic efficiency of 99.6% after 200 cycles.
